(19) United States
(12) Patent Application Publication
(10) Pub. No.: US 2023/0231077 A1
(43) Pub. Date: Jul. 20, 2023

(54) SEMICONDUCTOR LIGHT-EMITTING ELEMENT AND METHOD OF MANUFACTURING SEMICONDUCTOR LIGHT-EMITTING ELEMENT

(71) Applicant: NIKKISO CO., LTD., Tokyo (JP)

(72) Inventors: Noritaka NIWA, Ishikawa (JP); Tetsuhiko INAZU, Ishikawa (JP)

(21) Appl. No.: 18/155,967

(22) Filed: Jan. 18, 2023

(30) Foreign Application Priority Data
Jan. 18, 2022 (JP) 2022-005620

(51) Int. Cl. H01L 33/32; H01L 33/38; H01L 33/00

(52) U.S. Cl. CPC H01L 33/32; H01L 33/382; H01L 33/0075; H01L 33/0095

(57) ABSTRACT

A semiconductor light-emitting element includes: an n-type semiconductor layer made of an n-type AlGaN-based semiconductor material; an active layer provided on a first upper surface of the n-type semiconductor layer and made of an AlGaN-based semiconductor material; a p-type semiconductor layer provided on the active layer; an n-side contact electrode that includes a Ti layer in contact with a second upper surface of the n-type semiconductor layer, an Al layer provided on the Ti layer, and a nitride layer that covers the Al layer. The nitride layer includes a first portion made of TiN and a second portion containing TiAlN.

### RELATED APPLICATION

Priority is claimed to Japanese Patent Application No. 2022-005620, filed on Jan. 18, 2022, the entire content of which is incorporated herein by reference.

### BACKGROUND OF THE INVENTION

### 1. Field of the Invention

The present invention relates to a semiconductor light-emitting element and a method of manufacturing a semiconductor light-emitting element.

### 2. Description of the Related Art

An electrode containing Ti and Al is used as an electrode for ohmic contact formed on the surface of an n-type AlGaN-based semiconductor material. A nitride layer covering the Al layer is provided to prevent oxidation of the Al surface in the annealing step (see, for example, JP2020-87964).

A portion of the Al layer included in the electrode may be corroded in the lithographic step after the annealing step. It is preferable that corrosion of the Al layer be prevented in order to improve the reliability of a semiconductor light-emitting element.

### SUMMARY OF THE INVENTION

The present invention addresses the issue described above, and a purpose thereof is to provide a technology for improving the reliability of a semiconductor light-emitting element.

A semiconductor light-emitting element according to an aspect of the present invention includes: an n-type semiconductor layer made of an n-type AlGaN-based semiconductor material; an active layer provided on a first upper surface of the n-type semiconductor layer and made of an AlGaN-based semiconductor material; a p-type semiconductor layer provided on the active layer; an n-side contact electrode that includes a Ti layer in contact with a second upper surface of the n-type semiconductor layer, an Al layer provided on the Ti layer, and a nitride layer that covers the Al layer. The nitride layer includes a first portion made of TiN and a second portion containing TiAlN.

Another aspect of the present invention relates to a method of manufacturing a semiconductor light-emitting element. The method includes: forming an active layer made of an AlGaN-based semiconductor material on a first upper surface of an n-type semiconductor layer made of an n-type AlGaN-based semiconductor material; forming a p-type semiconductor layer on the active layer; removing the p-type semiconductor layer and the active layer in part to expose the second upper surface of the n-type semiconductor layer; forming a stack including a first Ti layer in contact with the second upper surface of the n-type semiconductor layer, an Al layer on the first Ti layer, a second Ti layer on the Al layer, and a TiN layer on the second Ti layer; annealing the stack; and forming a nitride layer on a surface of the stack by treating the annealed surface of the stack with an ammonia plasma.

### BRIEF DESCRIPTION OF THE DRAWINGS

FIG. 1 is a cross sectional view schematically showing a configuration of a semiconductor light-emitting element according to the embodiment;

FIG. 2 schematically shows a step of manufacturing the semiconductor light-emitting element;

FIG. 3 schematically shows a step of manufacturing the semiconductor light-emitting element;

FIG. 4 schematically shows a step of manufacturing the semiconductor light-emitting element;

FIG. 5 schematically shows a step of manufacturing the semiconductor light-emitting element;

FIG. 6 schematically shows a step of manufacturing the semiconductor light-emitting element;

FIG. 7 schematically shows a step of manufacturing the semiconductor light-emitting element;

FIG. 8 schematically shows a step of manufacturing the semiconductor light-emitting element; and

FIG. 9 schematically shows a step of manufacturing the semiconductor light-emitting element.

### DETAILED DESCRIPTION OF THE INVENTION

The invention will now be described by reference to the preferred embodiments. This does not intend to limit the scope of the present invention, but to exemplify the invention.

A detailed description will be given of an embodiment of the present invention with reference to the drawings. The same numerals are used in the description to denote the same elements and a duplicate description is omitted as appropriate. To facilitate the understanding, the relative dimensions of the constituting elements in the drawings do not necessarily mirror the relative dimensions in the actual light-emitting element.

The semiconductor light-emitting element according to the embodiment is configured to emit “deep ultraviolet light” having a central wavelength λ of about 360 nm or shorter and is a so-called deep ultraviolet-light emitting diode (DUV-LED) chip. To output deep ultraviolet light having such a wavelength, an aluminum gallium nitride (AlGaN)-based semiconductor material having a band gap of about 3.4 eV or larger is used. The embodiment particularly shows a case of emitting deep ultraviolet light having a central wavelength λ of about 240 nm-320 nm.

In this specification, the term “AlGaN-based semiconductor material” refers to a semiconductor material containing at least aluminum nitride (AlN) and gallium nitride (GaN) and shall encompass a semiconductor material containing other materials such as indium nitride (InN). Therefore, “AlGaN-based semiconductor materials” as recited in this specification can be represented by a composition In_{1-x-y}AlₓGa_{y}N (0<x+y≤1, 0<x<1, 0<y<1). The AlGaN-based semiconductor material shall encompass AlGaN or InAlGaN. The “AlGaN-based semiconductor material” in this specification has, for example, a molar fraction of AlN and a molar fraction of GaN equal to or more than 1% and, preferably, equal to or more than 5%, equal to or more than 10%, or equal to or more than 20%.

Those materials that do not contain AlN may be distinguished by referring to them as “GaN-based semiconductor materials”. “GaN-based semiconductor materials” contain GaN or InGaN. Similarly, those materials that do not contain GaN may be distinguished by referring to them as “AlN-based semiconductor materials”. “AlN-based semiconductor materials” contain AlN or InAlN.

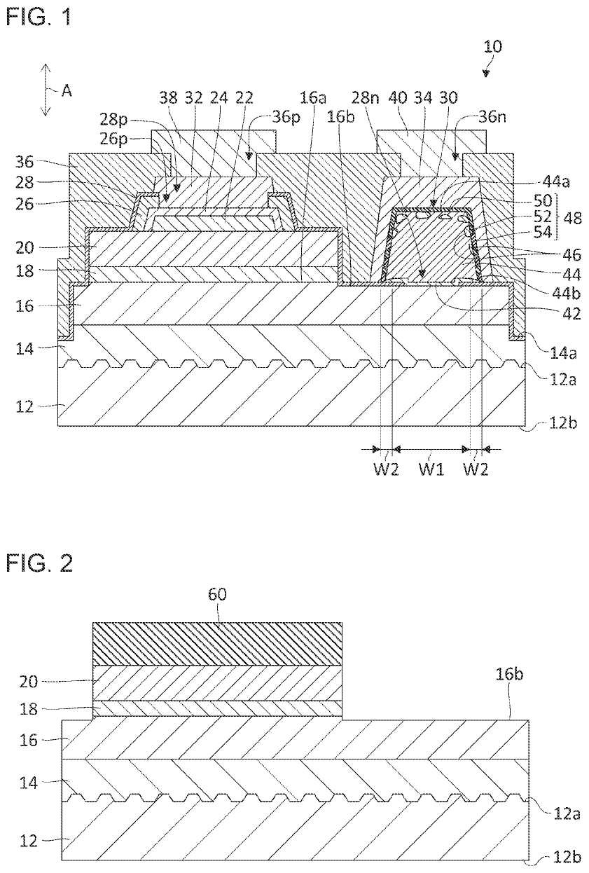

FIG. 1 is a cross sectional view schematically showing a configuration of a semiconductor light-emitting element 10 according to the embodiment. The semiconductor light-emitting element 10 includes a substrate 12, a base layer 14, an n-type semiconductor layer 16, an active layer 18, a p-type semiconductor layer 20, a p-side contact electrode 22, a p-side covering electrode layer 24, a dielectric protective layer 26, a dielectric covering layer 28, an n-side contact electrode 30, a p-side current diffusion layer 32, an n-side current diffusion layer 34, a dielectric sealing layer 36, a p-side pad electrode 38, and an n-side pad electrode 40.

Referring to FIG. 1, the direction indicated by the arrow A may be referred to as “vertical direction” or “direction of thickness”. Further, the direction away from the substrate 12 may be defined as “upward”, and the direction toward the substrate 12 may be defined as “downward”.

The substrate 12 is made of a material having translucency for the deep ultraviolet light emitted by the semiconductor light-emitting element 10 and is made of, for example, sapphire (Al₂O₃). The substrate 12 includes a first principal surface 12a and a second principal surface 12b opposite to the first principal surface 12a. The first principal surface 12a is a crystal growth surface for growing the layers from the base layer 14 to the p-type semiconductor layer 20. The first principal surface 12a has a fine concave-convex pattern having a submicron (equal to or less than 1 μm) depth and pitch. The substrate 12 like this is also called a patterned sapphire substrate (PSS). The first principal surface 12a may be comprised of a flat surface that is not patterned. The second principal surface 12b is a light extraction surface for extracting the deep ultraviolet light emitted by the active layer 18 outside.

The base layer 14 is provided on the first principal surface 12a of the substrate 12. The base layer 14 is a foundation layer (template layer) to form the n-type semiconductor layer 16. For example, the base layer 14 is an undoped AlN layer and is an AlN (HT-AlN; High Temperature-AlN) layer gown at a high temperature. The base layer 14 may be an undoped AlGaN layer. The base layer 14 may include an ALN layer and an undoped AlGaN layer provided on the AlN layer. The base layer 14 has a thickness equal to or more than 1 μm and equal to or less than 3 μm. For example, the base layer 14 has a thickness of about 2 μm.

The n-type semiconductor layer 16 is provided on the base layer 14. The n-type semiconductor layer 16 is made of an n-type AlGaN-based semiconductor material. For example, the n-type semiconductor layer 16 is doped with Si as an n-type impurity. The AlN ratio of the n-type semiconductor layer 16 is, for example, equal to or more than 25% and, preferably, equal to or more than 40% or equal to or more than 50%. The AlN ratio of the n-type semiconductor layer 16 is, for example, equal to or less than 80% and, preferably, equal to or less than 70%. The n-type semiconductor layer 16 has a thickness equal to or more than 1 μm and equal to or less than 3 μm. For example, the n-type semiconductor layer 16 has a thickness of about 2 μm. The n-type semiconductor layer 16 includes a first upper surface 16a and a second upper surface 16b. The first upper surface 16a is where the active layer 18 is formed, and the second upper surface 16b is where the active layer 18 is not formed.

The active layer 18 is provided on the first upper surface 16a of the n-type semiconductor layer 16. The active layer 18 is made of an AlGaN-based semiconductor material and has a double heterojunction structure by being sandwiched between the n-type semiconductor layer 16 and the p-type semiconductor layer 20. The AlN ratio of the active layer 18 is selected so as to output deep ultraviolet light having a wavelength equal to or less than 355 nm and, for example, equal to or less than 320 nm.

For example, the active layer 18 has a monolayer or multilayer quantum well structure and is comprised of a barrier layer made of an undoped AlGaN-based semiconductor material and a well layer made of an undoped AlGaN-based semiconductor material. The active layer 18 includes, for example, a first barrier layer directly in contact with the n-type semiconductor layer 16 and a first well layer provided on the first barrier layer. One or more pairs of the barrier layer and the well layer may be additionally provided between the first well layer and the p-type semiconductor layer 20. Each of the barrier layer and the well layer has a thickness equal to or more than 1 nm and equal to or less than 20 nm, and has, for example, a thickness equal to or more than 2 nm and equal to or less than 10 nm.

An electron block layer may further be provided between the active layer 18 and the p-type semiconductor layer 20. The electron block layer is made of an undoped AlGaN-based semiconductor material. The AlN ratio of the electron block layer is equal to or more than 40% and, preferably, equal to or more than 50%. The AlN ratio of the electron block layer may be equal to or more than 80%. The electron block layer may be made of an AlN-based semiconductor material that does not contain GaN or may be an AlN layer. The electron blocking layer has a thickness equal to or more than 1 nm and equal to or less than 10 nm. For example, the electron blocking layer has a thickness equal to or more than 2 nm and equal to or less than 5 nm.

The p-type semiconductor layer 20 is formed on the active layer 18. When an electron block layer is provided, the p-type semiconductor layer 20 is formed on the electron block layer. The p-type semiconductor layer 20 is made of a p-type AlGaN-based semiconductor material or a p-type GaN-based semiconductor material. For example, the p-type semiconductor layer 20 is an AlGaN layer or a GaN layer doped with magnesium (Mg) as a p-type impurity. The p-type semiconductor layer 20 has, for example, a thickness equal to or more than 20 nm and equal to or less than 400 nm.

The p-type semiconductor layer 20 may be comprised of a plurality of layers. The p-type semiconductor layer 20 may include, for example, a p-type clad layer and a p-type contact layer. The p-type clad layer is a p-type AlGaN layer having a relatively high AlN ratio as compared with the p-type contact layer and is directly in contact with the active layer 18 or the electron block layer. The p-type contact layer is a p-type AlGaN layer or a p-type GaN layer having a relatively low AlN ratio as compared with the p-type clad layer. The p-type contact layer is provided on the p-type clad layer and is directly in contact with the p-side contact electrode 22. The p-type clad layer may include a p-type first clad layer and a p-side second clad layer.

The AlN ratio of the p-type first clad layer is larger than the AlN ratio of the p-side second clad layer. The AlN ratio of the p-type first clad layer is, for example, similar to the AlN ratio of the n-type semiconductor layer 16 or larger than the AlN ratio of the n-type semiconductor layer 16. The AlN ratio of the p-type first clad layer is equal to or more than 25% and, preferably, equal to or more than 40% or equal to or more than 50%. The AlN ratio of the p-type first clad layer may be equal to or more than 70% or equal to more than 80%. The p-type first clad layer has a thickness equal to or more than 10 nm and equal to or less than 100 nm. For example, the p-type first clad layer has a thickness equal to or more than 15 nm and equal to or less than 70 nm.

The p-type second clad layer is provided on the p-type first clad layer. The AlN ratio of the p-type second clad layer is lower than the AlN ratio of the p-type first clad layer and is higher than the AlN ratio of the p-type contact layer. The AlN ratio of the p-type second clad layer is equal to or more than 25% and, preferably, equal to or more than 40% or equal to or more than 50%. The AlN ratio of the p-type second clad layer is, for example, within a range of ±10% of the AlN ratio of the n-type semiconductor layer 16. The p-type second clad layer has a thickness equal to or more than 5 nm and equal to or less than 250 nm and has, for example, a thickness equal to or more than 10 nm and equal to or less than 150 nm. The p-type second clad layer may not be provided, and the p-type clad layer may be comprised only of the p-type first clad layer.

The p-type contact layer has a relatively low AlN ratio in order to obtain proper ohmic contact with the p-side contact electrode 22. The AlN ratio of the p-type contact layer is equal to or less than 20% and, preferably, equal to or less than 10%, equal to or less than 5%, or 0%. The p-type contact layer is a p-type AlGaN layer or a p-type GaN layer. The p-type contact layer may be made of a p-type GaN-based semiconductor material that does not substantially contain AlN. It is preferred to form the p-type contact layer to be thin to reduce the quantity of absorption of the deep ultraviolet light emitted by the active layer 18. The p-type contact layer has a thickness equal to or more than 5 nm and equal to or less than 30 nm and has, for example, a thickness equal to or more than 10 nm and equal to or less than 20 nm.

The p-side contact electrode 22 is provided on the p-type semiconductor layer 20. The p-side contact electrode 22 can be in ohmic contact with the p-type semiconductor layer 20 (for example, the p-type contact layer) and is made of a material having a high reflectivity for deep ultraviolet light. The p-side contact electrode 22 includes a Rh layer directly in contact with the p-type semiconductor layer 20. The p-side contact electrode 2 may be, for example, comprised only of the Rh layer. The thickness of the Rh layer included in the p-side contact electrode 22 is equal to or more than 50 nm and equal to or less than 200 nm and is, for example, equal to or more than 70 nm and equal to or less than 150 nm. The film density of the Rh layer included in the p-side contact electrode 22 is equal to or more than 12.0 g/cm³ and is, for example, equal to or more than 12.2 g/cm³ and equal to or less than 12.5 g/cm³. By configuring the film density of the Rh layer included in the p-side contact electrode 22 to be large, the function of the p-side contact electrode 22 as a reflection electrode can be enhanced. By configuring the film density of the Rh layer to be equal to or more than 12 g/cm³, the reflectivity equal to or more than 65% for deep ultraviolet light having a wavelength of 280 nm can be obtained.

The embodiment is non-limiting as to the configuration of the p-side contact electrode 22, and the p-side contact electrode 22 may not be comprised only of the Rh layer. For example, the p-side contact electrode 22 may be made of an arbitrary metal material or made of a transparent conductive oxide (TCO) such as indium tin oxide (ITO).

The p-side covering electrode layer 24 is directly in contact with the upper surface and the side surface of the p-side contact electrode 22 and covers the entirety of the p-side contact electrode 22. The p-side covering electrode layer 24 has, for example, a Ti/Rh/TiN stack structure. The thickness of the Ti layer of the p-side covering electrode layer 24 is equal to or more than 1 nm and equal to or less than 50 nm and is, for example, equal to or more than 5 nm and equal to or less than 25 nm. The Ti layer of the p-side covering electrode layer 24 increases adhesion between the Rh layer of the p-side contact electrode 22 and the Rh layer of the p-side covering electrode layer 24. The thickness of the Rh layer of the p-side covering electrode layer 24 is equal to or more than 5 nm and equal to or less than 100 nm and is, for example, equal to or more than 10 nm and equal to or less than 50 nm. The TiN layer of the p-side covering electrode layer 24 is made of titanium nitride (TiN) having conductivity. The thickness of the TiN layer of the p-side covering electrode layer 24 is equal to or more than 5 nm and equal to or less than 100 nm and is, for example, equal to or more than 10 nm and equal to or less than 50 nm.

The dielectric protective layer 26 has a first connection opening 26p and covers the p-side contact electrode 22 and the p-side covering electrode layer 24 in a portion different from the first connection opening 26p. The dielectric protective layer 26 is directly in contact with the upper surface and the side surface of the p-side covering electrode layer 24 and is directly in contact with a portion of the upper surface of the p-type semiconductor layer 20. The dielectric protective layer 26 is made of a dielectric material and is made of, for example, silicon oxide (SiO2). The thickness of the dielectric protective layer 26 is equal to or more than 50 nm and is, for example, equal to or more than 100 nm and equal to or less than 500 nm.

The dielectric covering layer 28 covers the base layer 14, the n-type semiconductor layer 16, the active layer 18, the p-type semiconductor layer 20, the p-side contact electrode 22, the p-side covering electrode layer 24, and the dielectric protective layer 26. The dielectric covering layer 28 is made of a dielectric material different from that of the dielectric protective layer 26 and is made of, for example, Al₂O₃. The thickness of the dielectric covering layer 28 is equal to or more than 10 nm and equal to or less than 100 nm and is, for example, equal to or more than 20 nm and equal to or less than 50 nm.

The dielectric covering layer 28 is directly in contact with an outer circumferential surface 14a of the base layer 14. The dielectric covering layer 28 is directly in contact with the second upper surface 16b of the n-type semiconductor layer 16 and is directly in contact with the side surface (mesa surface) of the n-type semiconductor layer 16. The dielectric covering layer 28 is directly in contact with the side surface (mesa surface) of the active layer 18. The dielectric covering layer 28 is directly in contact with the side surface (mesa surface) of the p-type semiconductor layer 20 and is directly in contact with a portion of the upper surface of the p-type semiconductor layer 20. The dielectric covering layer 28 has a contact opening 28n provided on the second upper surface 16b of the n-type semiconductor layer 16 and covers the second upper surface 16b of the n-type semiconductor layer 16 in a portion different from the contact opening 28n. The dielectric covering layer 28 is directly in contact with the upper surface and the side surface of the dielectric protective layer 26. The dielectric covering layer 28 has a second connection opening 28p and covers the dielectric protective layer 26 in a portion different from the second connection opening 28p. The second connection opening 28p is located above the p-side contact electrode 22 and the p-side covering electrode layer 24.

The n-side contact electrode 30 is provided on the second upper surface 16b of the n-type semiconductor layer 16. The n-side contact electrode 30 is provided to block the contact opening 28n and overlaps the dielectric covering layer 28 outside the contact opening 28n. The n-side contact electrode 30 includes a Ti layer 42, an Al layer 44, a granular part 46, and a nitride layer 48.

The Ti layer 42 is directly in contact with the second upper surface 16b of the n-type semiconductor layer 16. The thickness of the Ti layer 42 is equal to or more than 1 nm and equal to or less than 10 nm and, preferably, equal to or less than 5 nm or equal to or less than 2 nm.

The Al layer 44 is provided on the Ti layer 42 and is directly in contact with the Ti layer 42. The thickness of the Al layer 44 is equal to or more than 200 nm and is, for example, equal to or more than 300 nm and equal to or less than 1000 nm. A side surface 44b of the Al layer 44 is configured to be sloped with respect to the second upper surface 16b. The granular part 46 is distributed in the neighborhood of an upper surface 44a and the side surface 44b of the Al layer 44. The granular part 46 contains Ti and contains Ti as a main component. The granular part 46 may contain Al and may contain TiAl. The size of the granular part 46 is equal to or more than 10 nm and equal to or less than 500 nm and is, for example, equal to or more than 50 nm and equal to or less than 200 nm.

The nitride layer 48 covers the upper surface 44a and the side surface 44b of the Al layer 44. The nitride layer 48 is made of TiN, TiAlN, or AlN. The thickness of the nitride layer 48 is equal to or more than 5 nm and equal to or less than 100 nm and is, for example, equal to or more than 10 nm and equal to or less than 50 nm.

The nitride layer 48 includes a first portion 50, a second portion 52, and a third portion 54. The first portion 50 is a portion made of TiN. The first portion 50 is provided in a first region W1, which is the central portion of the n-side contact electrode 30, and is directly in contact with the Al layer 44 or the granular part 46. The first portion 50 covers the upper surface 44a of the Al layer 44 in the first region W1. The first portion 50 may cover the side surface 44b of the Al layer 44 in the first region W1. The second portion 52 is provided in a second region W2, which is the outer circumferential portion of the n-side contact electrode 30. The second portion 52 contains TiAlN. The second portion 52 may be directly in contact with the granular part 46 in the second region W2. The third portion 54 is provided in the second region W2. The third portion 54 is a portion made of AlN. The third portion 54 is directly in contact with the side surface 44b of the Al layer in the second region W2.

The p-side current diffusion layer 32 is provided on the p-side covering electrode layer 24 and is directly in contact with the p-side covering electrode layer 24 in the connection opening (the first connection opening 26p and the second connection opening 28p). The p-side current diffusion layer 32 is provided to block the first connection opening 26p and the second connection opening 28p and is directly in contact with the dielectric covering layer 28 outside the second connection opening 28p. The p-side current diffusion layer 32 has, for example, a TiN/Ti/Rh/TiN/Ti/Au stack structure.

The n-side current diffusion layer 34 is directly in contact with the upper surface and the side surface of the n-side contact electrode 30 and covers the n-side contact electrode 30. The n-side current diffusion layer 34 is directly in contact with the dielectric covering layer 28 outside the n-side contact electrode 30. The n-side current diffusion layer 34 is configured similarly as the p-side current diffusion layer 32 and has, for example, a TiN/Ti/Rh/TiN/Ti/Au stack structure.

The dielectric sealing layer 36 is directly in contact with and covers the dielectric covering layer 28, the p-side current diffusion layer 32, and the n-side current diffusion layer 34. The dielectric sealing layer 36 includes a p-side pad opening 36p provided on the p-side current diffusion layer 32 and an n-side pad opening 36n provided on the n-side current diffusion layer 34. The dielectric sealing layer 36 covers the p-side current diffusion layer 32 in a portion different from the p-side pad opening 36p and covers the n-side current diffusion layer 34 in a portion different from the n-side pad opening 36n. The dielectric sealing layer 36 is made of a dielectric material different from that of the dielectric covering layer 28 and is made of, for example, SiO₂. The thickness of the dielectric sealing layer 36 is equal to or more than 300 nm and equal to or less than 1500 nm and is, for example, equal to or more than 600 nm and equal to or less than 1000 nm.

The p-side pad electrode 38 is provided on the p-side current diffusion layer 32 and is connected to the p-side current diffusion layer 32 in the p-side pad opening 36p. The p-side pad electrode 38 is provided to block the p-side pad opening 36p and is directly in contact with the dielectric sealing layer 36 outside the p-side pad opening 36p. The p-side pad electrode 38 is electrically connected to the p-side contact electrode 22 via the p-side current diffusion layer 32 and the p-side covering electrode layer 24.

The n-side pad electrode 40 is provided on the n-side current diffusion layer 34 and is connected to the n-side current diffusion layer 34 in the n-side pad opening 36n. The n-side pad electrode 40 is provided to block the n-side pad opening 36n and is directly in contact with the dielectric sealing layer 36 outside the n-side pad opening 36n. The n-side pad electrode 40 is electrically connected to the n-side contact electrode 30 via the n-side current diffusion layer 34.

The p-side pad electrode 38 and the n-side pad electrode 40 are portions bonded when the semiconductor light-emitting element 10 is mounted on a package substrate or the like. The p-side pad electrode 38 and the n-side pad electrode 40 include, for example, a Ni/Au, Ti/Au, or Ti/Pt/Au stack structure. The thickness of each of the p-side pad electrode 38 and the n-side pad electrode 40 is equal to or more than 100 nm and is, for example, equal to or more than 200 nm and equal to or less than 1000 nm.

A description will now be given of a method of manufacturing the semiconductor light-emitting element 10. FIGS. 2-9 schematically show steps of manufacturing the semiconductor light-emitting element 10. Referring to FIG. 2, the base layer 14, the n-type semiconductor layer 16, the active layer 18, and the p-type semiconductor layer 20 are first formed on the first principal surface 12a of the substrate 12 successively. The base layer 14, the n-type semiconductor layer 16, the active layer 18, and the p-type semiconductor layer 20 can be formed by a well-known epitaxial growth method such as the metal organic vapor phase epitaxy (MOVPE) method and the molecular beam epitaxy (MBE) method.

Subsequently, as shown in FIG. 2, a first mask 60 is formed on the p-type semiconductor layer 20 by using, for example, a publicly known lithographic technology. Subsequently, the second upper surface 16b of the n-type semiconductor layer 16 is formed in a region not overlapping the first mask 60 by dry-etching the active layer 18 and the p-type semiconductor layer 20 from above the first mask 60. The first mask 60 is then removed.

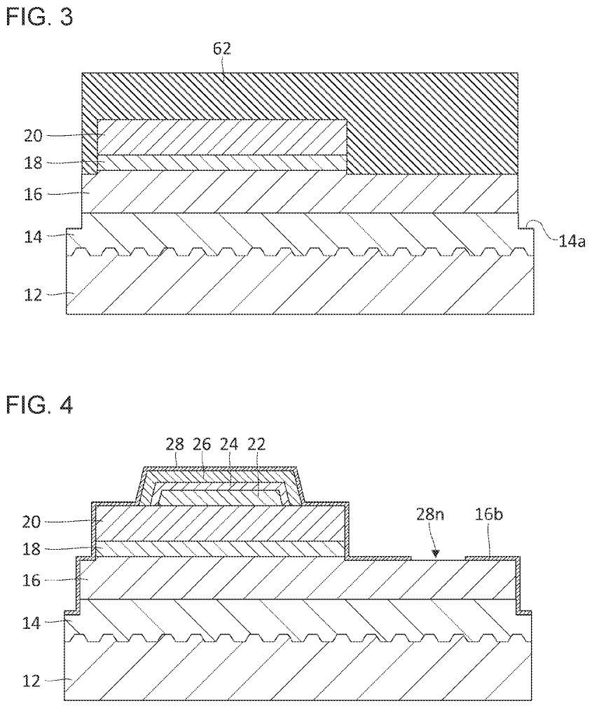

Subsequently, as shown in FIG. 3, a second mask 62 is formed to cover the n-type semiconductor layer 16, the active layer 18, and the p-type semiconductor layer 20 by using, for example, a publicly known lithographic technology. Subsequently, the outer circumferential surface 14a of the base layer 14 is formed in a region not overlapping the second mask 62 by dry-etching the n-type semiconductor layer 16 from above the second mask 62. The second mask 62 is then removed.

Referring to FIG. 4, the p-side contact electrode 22 is then formed on the p-type semiconductor layer 20 by using, for example, a publicly known lithographic technology. The p-side contact electrode 22 includes a Rh layer directly in contact with the upper surface of the p-type semiconductor layer 20. The Rh layer of the p-side contact electrode 22 is formed by deposition at a temperature equal to or less than 100° C. By forming the Rh layer by deposition, the damage to the upper surface of the p-type semiconductor layer 20 can be reduced and the contact resistance of the p-side contact electrode 22 can be improved as compared with the case of using sputtering.

After the p-side contact electrode 22 is formed, the p-side contact electrode 22 is annealed. The p-side contact electrode 22 is annealed by using, for example, the rapid thermal annealing (RTA) method at a temperature equal to or more than 500° C. and equal to or less than 650° C. The annealing process of the p-side contact electrode 22 lowers the contact resistance of the p-side contact electrode 22 and increases the film density of the Rh layer included in the p-side contact electrode 22 to be equal to or more than 12 g/cm³. The annealed Rh layer has, for example, a film density equal to or more than 12.2 g/cm³ and equal to or less than 12.5 g/cm³ and has a reflectivity equal to or more than 65% and, for example, a reflectivity of about 66%-67%, for ultraviolet light having a wavelength of 280 nm.

Referring to FIG. 4, the p-side covering electrode layer 24 is then formed to cover the entirety of the p-side contact electrode 22 by using, for example, a publicly known lithographic technology. The p-side covering electrode layer 24 is in contact with the upper surface and the side surface of the p-side contact electrode 22 and has, for example, a Ti/Rh/TiN stack structure. The p-side covering electrode layer 24 is formed by, for example, sputtering at a temperature equal to or less than 100° C. Formation of the p-side covering electrode layer 24 by sputtering can increase adhesion of the p-side covering electrode layer 24 to the p-side contact electrode 22.

Referring to FIG. 4, the dielectric protective layer 26 is then formed to cover the entirety of the p-side covering electrode layer 24 by using, for example, a publicly known lithographic technology. The dielectric protective layer 26 is made of, for example, SiO₂ and can be formed by plasma enhanced chemical vapor deposition (PECVD).

Referring to FIG. 4, the dielectric covering layer 28 is then formed. The dielectric covering layer 28 is formed over the entirety of the upper surface of the element structure to cover the base layer 14, the n-type semiconductor layer 16, the active layer 18, the p-type semiconductor layer 20, the p-side contact electrode 22, the p-side covering electrode layer 24, and the dielectric protective layer 26. The dielectric covering layer 28 is made of, for example, Al₂O₃ and can be formed by atomic layer deposition (ALD).

Referring to FIG. 4, the dielectric covering layer 28 is then removed in part by dry-etching or the like to form the contact opening 28n, by using, for example, a publicly known lithographic technology. The contact opening 28n is formed in a partial region on the second upper surface 16b of the n-type semiconductor layer 16. The contact opening 28n is formed to extend through the dielectric covering layer 28, and the second upper surface 16b of the n-type semiconductor layer 16 is exposed in the contact opening 28n.

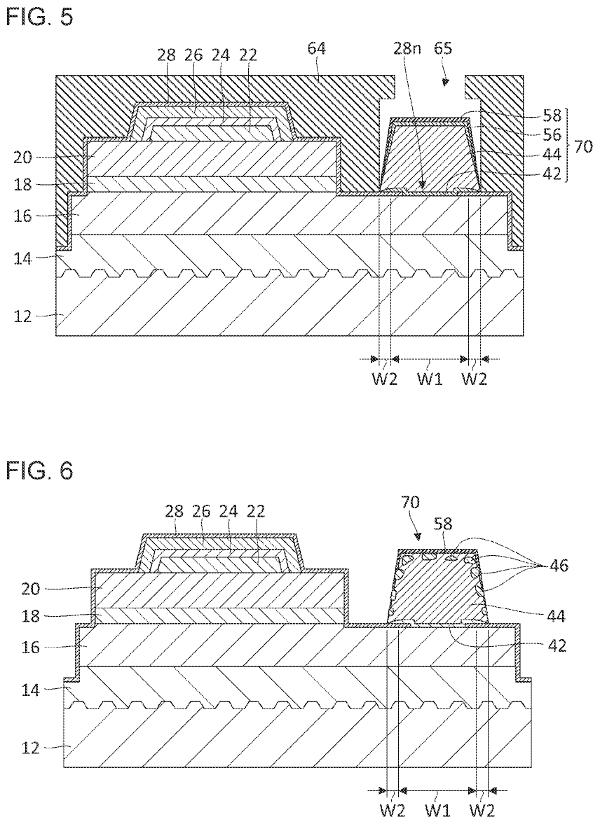

Subsequently, as shown in FIG. 5, a third mask 64 having an opening 65 of an undercut shape is formed by using, for example, a publicly known lithographic technology. The opening 65 of the third mask 64 is provided at a position corresponding to the contact opening 28n of the dielectric covering layer 28. The first Ti layer 42, the Al layer 44, a second Ti layer 56, and a TiN layer 58 are then stacked sequentially through the opening 65 of the third mask 64 to form a stack 70. The first Ti layer 42, the Al layer 44, the second Ti layer 56, and the TiN layer 58 can be formed by sputtering. The thickness of the second Ti layer 56 on the Al layer 44 is equal to or more than 1 nm and equal to or less than 50 nm and is, for example, equal to or more than 5 nm and equal to or less than 25 nm. The thickness of the TiN layer 58 is equal to or more than 5 nm and equal to or less than 100 nm and is, for example, equal to or more than 10 nm and equal to or less than 50 nm. In the presence of the opening 65 of an undercut shape, the thickness of each of the second Ti layer 56 and the TiN layer 58 is relatively smaller in the second region W2, which is the outer circumferential portion of the stack 70, than in the first region W1, which is the central portion of the stack 70. After the stack 70 is formed, the third mask 64 is removed.

The stack 70 is then annealed. The stack 70 is annealed by using, for example, the RTA method at a temperature equal to or more than 500° C. and equal to or less than 650° C. The annealing temperature of the stack 70 is near the melting temperature of the Al layer 44 so that the Al layer 44 is softened. When the Al layer 44 is softened, the second Ti layer 56 provided on the Al layer 44 becomes fluid, which turns Ti and Al into an alloy having a granular shape and forms the granular part 46 as shown in FIG. 6. The granular part 46 is originated from the second Ti layer 56 in the annealing step an contains Ti as a main component. At least a portion of the granular part 46 could be comprised of TiAl derived from a mixture of the Al layer 44 and the second Ti layer 56. When the granular part 46 is formed in the annealing step of the stack 70, at least a portion of the granular part 46 is exposed outside in the second region W2 in which the thickness of the TiN layer 58 is relatively small. Exposure of the granular part 46 causes the covering of the Al layer 44 provided by the TiN layer 58 to be disrupted in the second region W2.

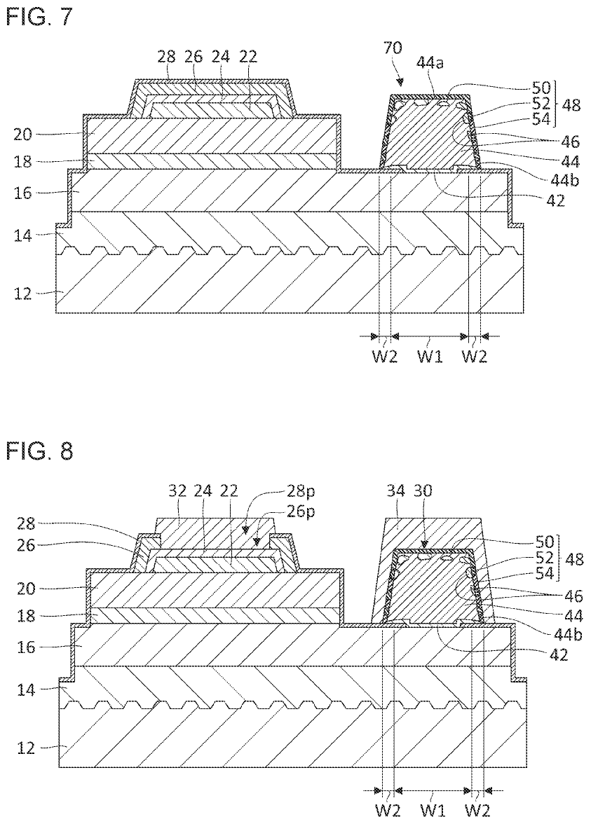

The surface of the stack 70 is then nitrided by treating the surface with an ammonia (NH3) plasma gas. Nitridation of the stack 70 forms the nitride layer 48 having the first portion 50, the second portion 52, and the third portion 54 as shown in FIG. 7. The first portion 50 is originated from the TiN layer 58 formed in the central portion (i.e., the first region W1). The second portion 52 is a portion formed by nitridation of the granular part 46 exposed outside and contains TiAlN. The third portion 54 is a portion formed by nitridation of the Al layer 44 exposed outside and contains AlN. The second portion 52 and the third portion 54 are formed in the outer circumferential portion (i.e., the second region W2) in which the thickness of the TiN layer is relatively small. Nitridation of the stack 70 is preferably performed at, for example, a low temperature lower than 300° C. Nitridation by a plasm treatment at a relatively low temperature like this makes it possible to form the nitride layer 48 on the entirety of the surface of the stack 70, while maintaining the structure of the annealed stack 70. The nitride layer 48 is formed to cover the entirety of the upper surface 44a and the side surface 44b of the Al layer 44. Nitridation of the surface of the stack 70 completes formation of the n-side contact electrode 30.

Referring to FIG. 8, the dielectric protective layer 26 and the dielectric covering layer 28 are then removed in part by dry-etching or the like to form the first connection opening 26p and the second connection opening 28p (which may also be generically referred to as connection openings), by using, for example, a publicly known lithographic technology. The second connection opening 28p is first formed to extend through the dielectric covering layer 28, and the first connection opening 26p is then formed to extend through the dielectric protective layer 26. The upper surface of the p-side covering electrode layer 24 is exposed in the first connection opening 26p.

The first connection opening 26p and the second connection opening 28p can be formed successively by using a common mask. The first connection opening 26p and the second connection opening 28p may be formed by using individual masks instead of a common mask. The second connection opening 28p may be formed after the n-side contact electrode 30 is formed or formed before the n-side contact electrode 30 is formed. For example, the second connection opening 28p may be formed concurrently when the contact opening 28n shown in FIG. 4 is formed.

Subsequently, as shown in FIG. 8, the p-side current diffusion layer 32 connected to the p-side covering electrode layer 24 in the connection opening (the first connection opening 26p and the second connection opening 28p) is formed, and the n-side current diffusion layer 34 is formed to cover the upper surface 28a and the side surface 28b of the n-side contact electrode 30. The p-side current diffusion layer 32 and the n-side current diffusion layer 34 have, for example, a TiN/Ti/Rh/TiN/Ti/Au stack structure. The p-side current diffusion layer 32 and the n-side current diffusion layer 34 can be formed concurrently by sputtering.

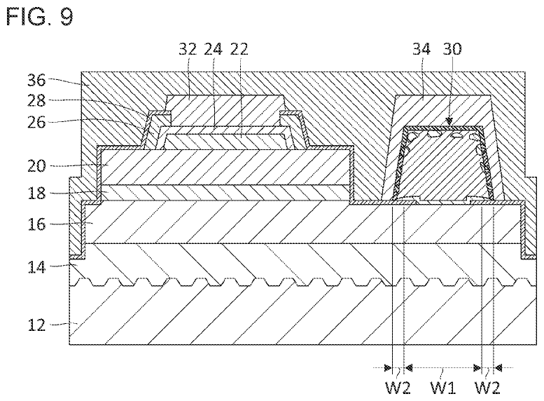

Subsequently, as shown in FIG. 9, the dielectric sealing layer 36 is formed. The dielectric sealing layer 36 is formed over the entirety of the upper surface of the element structure to be directly in contact with and cover the dielectric covering layer 28, the p-side current diffusion layer 32, and the n-side current diffusion layer 34. The dielectric sealing layer 36 is made of, for example, SiO₂ and can be formed by the PECVD method. The dielectric sealing layer 36 is formed at a temperature equal to or more than 200° C. and equal to or less than 300° C.

Subsequently, as shown in FIG. 1, the dielectric sealing layer 36 is removed in part by dry-etching or the like to form the p-side pad opening 36p and the n-side pad opening 36n. The p-side pad opening 36p and the n-side pad opening 36n are formed to extend through the dielectric sealing layer 36 to expose the p-side current diffusion layer 32 in the p-side pad opening 36p and expose the n-side current diffusion layer 34 in the n-side pad opening 36n. Subsequently, the p-side pad electrode 38 connected to the p-side current diffusion layer 32 in the p-side pad opening 36p is formed to block the p-side pad opening 36p, and the n-side pad electrode 40 connected to the n-side current diffusion layer 34 in the n-side pad opening 36n is formed to block the n-side pad opening 36n. The p-side pad electrode 38 and the n-side pad electrode 40 can be formed concurrently but can be formed separately.

The semiconductor light-emitting element 10 shown in FIG. 1 is completed through the steps described above.

According to the embodiment, TiAlN is contained at least in a portion of the nitride layer 48 so that the corrosion resistance of the n-side contact electrode 30 is increased as compared with the case of forming the nitride layer only by TiN. As a result, the reliability of the semiconductor light-emitting element 10 is improved.

According to the embodiment, the first portion 50 constituting the central portion of the nitride layer 48 is made of TiN having conductivity. Therefore, electric connection between the n-side contact electrode 30 and the n-side current diffusion layer 34 is secured. Meanwhile, the second portion 52 and the third portion constituting the outer circumferential portion of the nitride layer 48 are made of TiAlN and AlN so that the corrosion resistance of the n-side contact electrode 30 in the outer circumferential portion is increased.

According to the embodiment, the Al layer 44 and the granular part 46 exposed outside as a result of annealing are covered by the nitride layer 48 by nitriding the surface of the stack 70 after the stack 70 is annealed. As a result, the Al layer 44 and the granular part 46 are prevented from being corroded by the chemical used in the lithographic step shown in FIG. 8. As a result, the reliability of the semiconductor light-emitting element 10 is improved.

Described above is an explanation based on an exemplary embodiment. The embodiment is intended to be illustrative only and it will be understood by those skilled in the art that various design changes are possible and various modifications are possible and that such modifications are also within the scope of the present invention.

Some embodiments of the present invention will be described.

The first aspect of the present invention relates to a semiconductor light-emitting element including: an n-type semiconductor layer made of an n-type AlGaN-based semiconductor material; an active layer provided on a first upper surface of the n-type semiconductor layer and made of an AlGaN-based semiconductor material; a p-type semiconductor layer provided on the active layer; an n-side contact electrode that includes a Ti layer in contact with a second upper surface of the n-type semiconductor layer, an Al layer provided on the Ti layer, and a nitride layer that covers the Al layer, wherein the nitride layer includes a first portion made of TiN and a second portion containing TiAlN. According to the first aspect, the nitride layer covering the Al layer contains TiAlN so that the corrosion resistance of the nitride layer is increased. This improves the reliability of the semiconductor light-emitting element.

The second aspect of the present invention relates to the semiconductor light-emitting element according to the first aspect, wherein the first portion covers an upper surface of the Al layer, and the second portion covers a side surface of the Al layer. According to the second aspect, the side surface of the Al layer, for which the quality of covering by the nitride layer is easily lowered, is covered by the second portion containing TiAlN so that the corrosion resistance of the Al layer is further increased.

The third aspect of the present invention relates to the semiconductor light-emitting element according to the first or second aspect, wherein the second portion covers an outer circumferential portion of the Al layer. According to the third aspect, the outer circumferential portion of the Al layer, for which the quality of covering by the nitride layer is easily lowered, is covered by the second portion that contains TiAlN so that the corrosion resistance of the Al layer is further increased.

The fourth aspect of the present invention relates to the semiconductor light-emitting element according to any one of the first through third aspects, wherein a side surface of the Al layer is sloped with respect to the second upper surface. According to the fourth aspect, exfoliation of the nitride layer from the Al layer is suppressed by sloping the side surface of the Al layer so that the corrosion resistance of the Al layer is further increased.

The fifth aspect of the present invention relates to a method of manufacturing a semiconductor light-emitting element including: forming an active layer made of an AlGaN-based semiconductor material on a first upper surface of an n-type semiconductor layer made of an n-type AlGaN-based semiconductor material; forming a p-type semiconductor layer on the active layer; removing the p-type semiconductor layer and the active layer in part to expose the second upper surface of the n-type semiconductor layer; forming a stack including a first Ti layer in contact with the second upper surface of the n-type semiconductor layer, an Al layer on the first Ti layer, a second Ti layer on the Al layer, and a TiN layer on the second Ti layer; annealing the stack; and forming a nitride layer on a surface of the stack by treating the annealed surface of the stack with an ammonia plasma. According to the fifth aspect, the nitride layer is formed by nitriding the Al layer and the Ti layer exposed outside the stack after the stack is annealed so that the corrosion resistance of the Al layer included in the stack is increased. This improves the reliability of the semiconductor light-emitting element.

The sixth aspect of the present invention relates to the method of manufacturing a semiconductor light-emitting element according to the fifth aspect, wherein the nitride layer contains TiAlN. According to the sixth aspect, the nitride layer contains TiAlN so that the corrosion resistance of the nitride layer is further increased.

What is claimed is:

1. A semiconductor light-emitting element comprising:
an n-type semiconductor layer made of an n-type AlGaN-based semiconductor material;
an active layer provided on a first upper surface of the n-type semiconductor layer and made of an AlGaN-based semiconductor material;
a p-type semiconductor layer provided on the active layer;
an n-side contact electrode that includes a Ti layer in contact with a second upper surface of the n-type semiconductor layer, an Al layer provided on the Ti layer, and a nitride layer that covers the Al layer, wherein
the nitride layer includes a first portion made of TiN and a second portion containing TiAlN.

2. The semiconductor light-emitting element according to claim 1, wherein
the first portion covers an upper surface of the Al layer, and the second portion covers a side surface of the Al layer.

3. The semiconductor light-emitting element according to claim 1, wherein
the second portion covers an outer circumferential portion of the Al layer.

4. The semiconductor light-emitting element according to claim 1, wherein
a side surface of the Al layer is sloped with respect to the second upper surface.

5. The semiconductor light-emitting element according to claim 1, wherein
the n-side contact electrode further includes a granular part made of TiAl, and
the second portion of the nitride layer covers the granular part.

6. A method of manufacturing a semiconductor light-emitting element comprising:
forming an active layer made of an AlGaN-based semiconductor material on a first upper surface of an n-type semiconductor layer made of an n-type AlGaN-based semiconductor material;
forming a p-type semiconductor layer on the active layer;
removing the p-type semiconductor layer and the active layer in part to expose the second upper surface of the n-type semiconductor layer;
forming a stack including a first Ti layer in contact with the second upper surface of the n-type semiconductor layer, an Al layer on the first Ti layer, a second Ti layer on the Al layer, and a TiN layer on the second Ti layer;
annealing the stack; and
forming a nitride layer on a surface of the stack by treating the annealed surface of the stack with an ammonia plasma.

7. The method of manufacturing a semiconductor light-emitting element according to claim 6, wherein
the nitride layer contains TiAlN.
